(19) United States
(12) Patent Application Publication
(10) Pub. No.: US 2024/0194496 A1
(43) Pub. Date: Jun. 13, 2024

(54) SUBSTRATE PROCESSING APPARATUS AND SUBSTRATE PROCESSING METHOD

(71) Applicant: Tokyo Electron Limited, Tokyo (JP)

(72) Inventors: Shota UMEZAKI, Koshi City (JP); Mikio NAKASHIMA, Koshi City (JP); Takahiro HAYASHIDA, Koshi City (JP)

(21) Appl. No.: 18/533,256

(22) Filed: Dec. 8, 2023

(30) Foreign Application Priority Data
Dec. 13, 2022 (JP) 2022-198494
Sep. 28, 2023 (JP) 2023-167390

(51) Int. Cl. H01L 21/67

(52) U.S. Cl. CPC H01L 21/67023; H01L 21/67253

(57) ABSTRACT

A substrate processing apparatus includes: a processing container in which a substrate is accommodated; a holder configured to hold the substrate in a horizontal posture at a holding position inside the processing container; and a fluid supplier configured to supply, into the processing container, a supercritical processing fluid for drying the substrate to which a liquid adheres, wherein the fluid supplier includes a first direction change member configured to change a flow of the supercritical processing fluid, supplied radially outward from the substrate held by the holder, in a direction that does not come in contact with a radial outer end of the substrate.

### CROSS-REFERENCE TO RELATED APPLICATIONS

This application is based upon and claims the benefit of priority from Japanese Patent Application Nos. 2022-198494 and 2023-167390, filed on Dec. 13, 2022 and Sep. 28, 2023, respectively, the entire contents of which are incorporated herein by reference.

### TECHNICAL FIELD

The present disclosure relates to a substrate processing apparatus and a substrate processing method.

### BACKGROUND

In a semiconductor device manufacturing process of forming a stacked structure of an integrated circuit on a surface of a substrate, liquid processing such as chemical liquid cleaning, wet etching or the like is performed. A liquid or the like adhering to the surface of the substrate during the liquid processing is removed by, for example, a drying method using a processing fluid in a supercritical state (see, for example, Patent Document 1).

### PRIOR ART DOCUMENT

### Patent Document

Patent Document 1: Japanese Laid-Open Patent Publication No. 2013-012538

### SUMMARY

According to one embodiment of the present disclosure, a substrate processing apparatus includes: a processing container in which the substrate is accommodated; a holder configured to hold the substrate in a horizontal posture at a holding position inside the processing container; and a fluid supplier configured to supply, into the processing container, a supercritical processing fluid for drying the substrate to which a liquid adheres, wherein the fluid supplier includes a first direction change member configured to change a flow of the supercritical processing fluid which is supplied radially outward from the substrate held by the holder, in a direction that does not come in contact with a radial outer end of the substrate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic diagram illustrating a substrate processing apparatus according to an embodiment.

FIG. 2 is a horizontal cross-sectional view illustrating an example of a processor.

FIG. 3 is a flowchart illustrating a substrate processing method according to an embodiment.

FIG. 4 is a vertical cross-sectional view illustrating a first direction change member according to a first example.

FIG. 5 is a vertical cross-sectional view illustrating a first direction change member according to a second example.

FIG. 6 is a vertical cross-sectional view illustrating a first direction change member according to a third example.

FIG. 7 is a vertical cross-sectional view illustrating a first direction change member according to a fourth example.

FIGS. 8A and 8B illustrate a first direction change member according to a fifth example.

FIG. 9 is a horizontal cross-sectional view illustrating a second direction change member according to a first example.

FIG. 10 is a horizontal cross-sectional view illustrating a second direction change member according to a second example.

FIG. 11 is a vertical cross-sectional view illustrating a second direction change member according to a third example.

FIG. 12 is a schematic perspective view illustrating a fluid supplier according to a modification.

FIG. 13 is a vertical cross-sectional view illustrating a fluid supplier according to a modification.

### DETAILED DESCRIPTION

Hereinafter, non-limiting exemplary embodiments of the present disclosure will be described with reference to the accompanying drawings. In all of the accompanying drawings, identical or corresponding members or components are designated by the same or corresponding reference numerals, and redundant descriptions thereof will be omitted. In the present specification, an X-axis direction, a Y-axis direction, and a Z-axis direction are perpendicular to one another. The X-axis direction and the Y-axis direction are horizontal directions, and the Z-axis direction is a vertical direction. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Substrate Processing Apparatus>

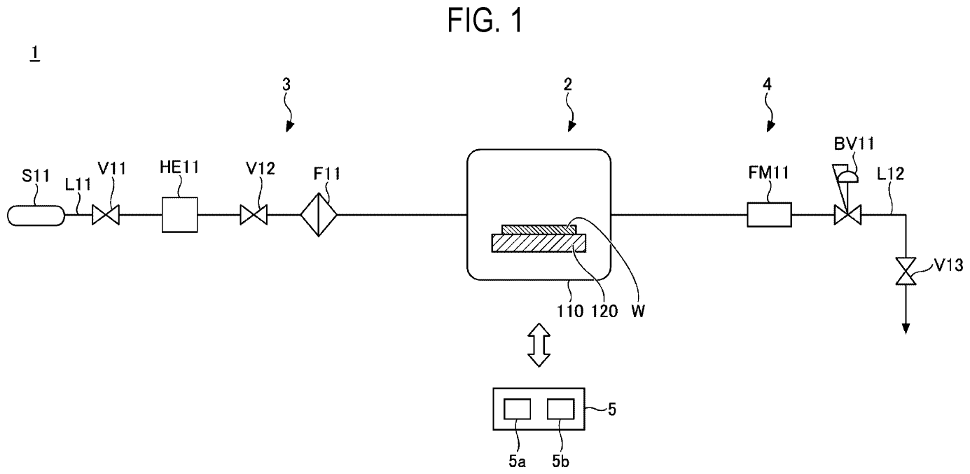

A substrate processing apparatus 1 according to an embodiment will be described with reference to FIG. 1. FIG. 1 is a schematic diagram illustrating the substrate processing apparatus 1 according to an embodiment.

The substrate processing apparatus 1 is an apparatus for drying a liquid adhering to a substrate W with a supercritical processing fluid. The substrate processing apparatus 1 includes a processor 2, a fluid supply system 3, a discharger 4, and a controller 5.

The processor 2 includes a processing container 110 and a holder 120. The processing container 110 is a container having an internal processing space in which the substrate W is accommodated. The substrate W may be, for example, a semiconductor wafer. The holder 120 is provided inside the processing container 110. The holder 120 holds the substrate W in a horizontal posture at a holding position inside the processing container 110. The processor 2 may include a pressure sensor for detecting an internal pressure of the processing container 110 and a temperature sensor for detecting an internal temperature of the processing container 110. The processor 2 will be described in detail later.

The fluid supply system 3 includes a supply channel L11. The supply channel L11 is connected to the processing container 110. The supply channel L11 supplies fluid into the processing container 110. A fluid source S11, an opening/closing valve V11, a heating mechanism HE11, an opening/closing valve V12, and a filter F11 are provided in the supply channel L11 in order from upstream. The supply channel L11 may also include an orifice, an opening/closing valve, a temperature sensor, a pressure sensor, a line heater and the like, which are not illustrated.

The fluid source S11 includes a source of the fluid. The fluid includes, for example, a processing fluid. The processing fluid may be, for example, carbon dioxide (CO₂). The fluid may include an inert gas. The inert gas may be, for example, a nitrogen (N₂) gas.

The opening/closing valve V11 is a valve that switches ON and OFF of a flow of the fluid. In the open state, the opening/closing valve V11 allows the fluid to flow to the heating mechanism HE11 on the downstream side, while in the closed state, the opening/closing valve V11 does not allow the fluid to flow to the heating mechanism HE11 on the downstream side.

The heating mechanism HE11 heats the fluid to a set temperature and supplies the fluid at the set temperature to the downstream side.

The opening/closing valve V12 is a valve that switches ON and OFF of the flow of the fluid. In the open state, the opening/closing valve V12 allows the fluid to flow to the filter F11 on the downstream side, while in the closed state, the opening/closing valve V12 does not allow the fluid to flow through the filter F11 on the downstream side.

The filter F11 filters the fluid flowing through the supply channel L11 to remove foreign matter contained in the fluid. By doing so, it is possible to suppress occurrence of particles on the surface of the substrate W during substrate processing using the fluid.

The discharger 4 includes a discharge channel L12. The discharge channel L12 is connected to the processing container 110. The discharge channel L12 discharges the fluid from the interior of the processing container 110. The discharge channel L12 is provided with a flow meter FM11, a back-pressure valve BV11, and an opening/closing valve V13 in order from the upstream side. The discharge channel L12 may also include an opening/closing valve, a temperature sensor, a pressure sensor, a line heater and the like, which are not illustrated.

The flow meter FM11 detects a flow rate of the fluid flowing through the discharge channel L12.

The back-pressure valve BV11, when a pressure on a primary side of the discharge channel L12 exceeds a set pressure, adjusts a valve opening to flow the fluid to a secondary side, thereby maintaining the pressure on the primary side at the set pressure. For example, the set pressure of the back-pressure valve BV11 is adjusted by the controller 5 based on an output of the flow meter FM11.

The opening/closing valve V13 is a valve that switches ON and OFF of the flow of the fluid. In the open state, the opening/closing valve V13 allows the fluid to flow to the discharge channel L12 on the downstream side, while in the closed state, the opening/closing valve V13 does not allow the fluid to flow through the discharge channel L12 on the downstream side.

The controller 5 receives measurement signals from various sensors and transmits control signals to various functional elements. The measurement signals include, for example, detection signals from the temperature sensor, detection signals from the pressure sensor, and detection signals from the flow meter FM11. The control signals include, for example, opening/closing signals from the opening/closing valves V11, V12 and V13 and a set pressure signal from the back-pressure valve BV1.

The controller 5 may be, for example, a computer. The controller 5 includes a calculator 5a and a memory 5b. The memory 5b stores programs for controlling various types of processing executed by the substrate processing apparatus 1. The calculator 5a controls the operation of the substrate processing apparatus 1 by reading and executing programs stored in the memory 5b. The programs may be recorded on a non-transitory computer-readable memory medium and installed in the memory 5b of the controller 5 from the memory medium. The computer-readable memory medium may be a hard disk (HD), a flexible disk (FD), a compact disk (CD), a magnetic optical disk (MO), a memory card, or the like.

### <Processor>

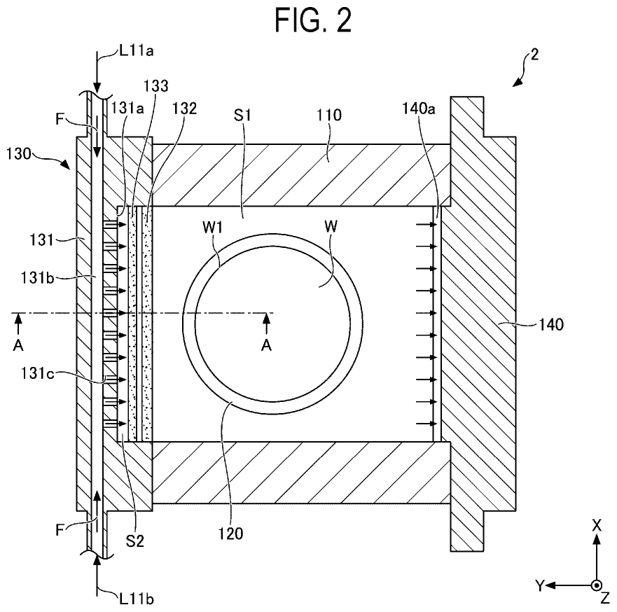

An example of the processor 2 will be described with reference to FIG. 2. FIG. 2 is a horizontal cross-sectional view illustrating the example of the processor 2.

The processor 2 includes a processing container 110, a holder 120, a fluid supplier 130, and a cover 140.

The processing container 110 has an internal processing space S1 in which the substrate W is accommodated. The processing space S1 is covered by the processing container 110 from the outside and partitioned. Both ends of the processing space S1 in the Y-axis direction are open without being covered by the processing container 110. Openings at the two ends of the processing space S1 face each other. The openings at the two ends of the processing space S1 are positioned to sandwich the substrate W held at the holding position.

The holder 120 is provided inside the processing container 110. The holder 120 holds the substrate W in a horizontal posture at the holding position inside the processing container 110.

The fluid supplier 130 includes a supply body 131, a first direction change member 132, and a second direction change member 133.

The supply body 131 covers an opening of the processing space S1 in a positive Y-axis direction. A sealing member (not illustrated) is disposed between the supply body 131 and the processing container 110. The sealing member ensures air tightness of the processing space S1 between the fluid supplier 130 and the processing container 110. The supply body 131 includes a concave portion 131a, an inner channel 131b, and a plurality of discharge ports 131c.

The concave portion 131a is provided at a side of the processing space S1 of the supply body 131. The concave portion 131a forms a supply space S2 communicating with the processing space S1.

The inner channel 131b is provided inside the supply body 131. The inner channel 131b extends in the X-axis direction. A first branch channel L11a and a second branch channel L11b, which are branched at the supply channel L11, are connected to openings at both ends of the inner channel 131b. A processing fluid F from the first branch channel L11a and the second branch channel L11b is supplied to the inner channel 131b.

The plurality of discharge ports 131c are provided along the inner channel 131b in the X-axis direction. Through each of the discharge ports 131c, the inner channel 131b and the supply space S2 are in communication with each other. Each of the discharge ports 131c is provided radially outward from the substrate W held at the holding position. Each of the discharge ports 131c discharges the processing fluid F toward the supply space S2. The plurality of discharge ports 131c may be dispersedly arranged over the entire range of the substrate W at the holding position in the X-axis direction. The plurality of discharge ports 131c may be arranged in multiple stages in the Z-axis direction.

The first direction change member 132 is provided between the substrate W held at the holding position and the plurality of discharge ports 131c. The first direction change member 132 is provided, for example, in the supply space S2. The first direction change member 132 may be provided in the processing space S1. The first direction change member 132 may be provided over the processing space S1 and the supply space S2. The first direction change member 132 may be detachably attached to the supply body 131. In this case, the first direction change member 132 may be easily replaced. The first direction change member 132 changes a flow of the processing fluid F, which is supplied to the supply space S2 from the plurality of discharge ports 131c, in a direction that does not come in contact with a radial outer end W1 of the substrate W held at the holding position. The first direction change member 132 forms the flow of the processing fluid F with a minimum distance of 0.5 mm or more from the radial outer end W1 of the substrate W. The first direction change member 132 will be described in detail later.

The second direction change member 133 is provided between the plurality of discharge ports 131c and the first direction change member 132. The second direction change member 133 is provided, for example, in the supply space S2. The second direction change member 133 may be provided in the processing space S1. The second direction change member 133 may be provided over the processing space S1 and the supply space S2. The second direction change member 133 may be detachably attached to the supply body 131. In this case, the second direction change member 133 may be easily replaced. The second direction change member 133 changes a horizontal flow of the processing fluid F supplied to the supply space S2 from the plurality of discharge ports 131c. The second direction change member 133 will be described in detail later.

The cover 140 covers an opening of the processing space S1 in a negative Y-axis direction. A sealing member (not illustrated) is provided between the cover 140 and the processing container 110. The sealing member ensures air tightness of the processing space S1 between the cover 140 and the processing container 110. A discharge port 140a is provided between the cover 140 and the processing container 110 in the negative Z-axis direction. The discharge port 140a is connected to the discharge channel L12. The processing fluid F in the processing space S1 is discharged via the discharge port 140a.

### <Substrate Processing Method>

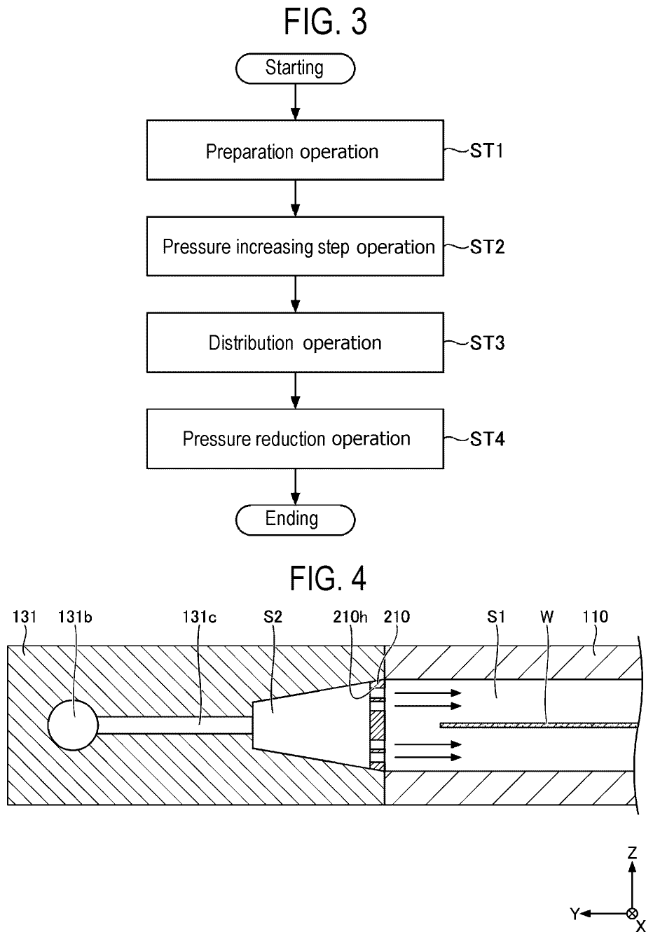

A substrate processing method executed using the substrate processing apparatus 1 will be described with reference to FIG. 3. The substrate processing method described below is automatically executed under the control of the controller 5 based on a processing recipe and a control program stored in the memory 5b. FIG. 3 is a flowchart illustrating the substrate processing method according to an embodiment. As illustrated in FIG. 3, the substrate processing method according to the embodiment includes a preparation operation ST1, a pressure increasing operation ST2, a distribution operation ST3, and a pressure reducing operation ST4.

In the preparation operation ST1, the substrate W is introduced into the processing container 110. The substrate W is loaded onto the holder 120 while being cleaned and filled with isopropyl alcohol (IPA) in a concave portion of a pattern of the surface of the substrate W.

The pressure increasing operation ST2 is performed after the preparation operation ST1. In the pressure increasing operation ST2, the opening/closing valves V11 and V12 are open and the opening/closing valve V13 is closed. As a result, a processing fluid of the fluid source S11 is discharged from the plurality of discharge ports 131c of the fluid supplier 130 into the processing container 110 via the supply channel L11, and the flow of the fluid is changed by the first direction change member 132 in a direction that does not come in contact with the radial outer end W1 of the substrate W. In the pressure increasing operation ST2, the opening/closing valve V13 is closed, and thus the processing fluid does not flow out of the processing container 110. Therefore, the internal pressure of the processing container 110 gradually increases. In the pressure increasing operation ST2, the pressure of the processing fluid supplied into the processing container 110 is lower than a threshold pressure. For this reason, the processing fluid is supplied into the processing container 110 in a gaseous state. Subsequently, the internal pressure of the processing container 110 increases with the progress of the filling of the processing fluid into the processing container 110. When the internal pressure of the processing container 110 exceeds the threshold pressure, the processing fluid present in the processing container 110 becomes a supercritical state. In the pressure increasing operation ST2, when the internal pressure of the processing container 110 reaches a predetermined pressure that is higher than the threshold pressure, the pressure increasing operation ST2 ends and the distribution operation ST3 is performed.

The distribution operation ST3 is performed after the pressure increasing operation ST2. In the distribution operation ST3, the opening/closing valves V11, V12 and V13 are open. As a result, the processing fluid of the fluid source S11 is discharged from the plurality of discharge ports 131c of the fluid supplier 130 into the processing container 110 via the supply channel L11, and the flow of the fluid is changed by the first direction change member 132 in a direction that does not come in contact with the radial outer end W1 of the substrate W. The processing fluid supplied into the processing container 110 is discharged from the interior of the processing container 110 via the discharge channel L12. In the distribution operation ST3, the supply of the processing fluid into the processing container 110 and the discharge of the processing fluid from the interior of the processing container 110 are performed simultaneously. By performing the distribution operation ST3, the replacement of the IPA with the processing fluid in the concave portion of the pattern of the substrate W is facilitated. When the replacement of the IPA with the processing fluid in the concave portion of the pattern is completed, the distribution operation ST3 ends and the pressure reducing operation ST4 is performed.

The pressure reducing operation ST4 is performed after the distribution operation ST3. In the pressure reducing operation ST4, the opening/closing valve V13 is open, and the opening/closing valves V11 and V12 are closed. As a result, the processing fluid is discharged from the interior of the processing container 110 in a state where the processing fluid is not supplied into the processing container 110. When the internal pressure of the processing container 110 is reduced below the threshold pressure of the processing fluid by the pressure reducing operation ST4, the processing fluid in the supercritical state is vaporized and released from the concave portion of the pattern. In this way, the drying process for one substrate W is terminated.

According to an embodiment, in the pressure increasing operation ST2, the flow of the processing fluid discharged into the processing container 110 from a radial outer side of the substrate W held at the holding position is changed by the first direction change member 132 in a direction that does not come in contact with the radial outer end W1 of the substrate W. This may suppress the pattern of the substrate W from collapsing. This point will be described below.

When a liquid film present on the surface of the substrate W is exposed to a flow of a gaseous processing fluid, the liquid film may evaporate, which may cause collapse of the pattern. In the pressure increasing operation ST2, when the gaseous processing fluid is supplied into the processing container 110 from the radial outer side of the substrate W, a relatively high-velocity flow of the processing fluid directly impacts the liquid film on the radial outer end W1 of the substrate. For this reason, the evaporation of the liquid film on the radial outer end W1 of the substrate W is prone to occur.

In contrast, in the embodiment, the processing fluid discharged into the processing container 110 from the radial outer side of the substrate W does not flow toward the radial outer end W1 of the substrate W, but is supplied to the substrate W after the flow is changed by the first direction change member 132 in a direction that does not come in contact with the radial outer end W1 of the substrate W. In other words, there is no flow of the processing fluid directly toward the radial outer end W1 of the substrate W. For this reason, the evaporation of the liquid film on the radial outer end W1 of the substrate W, which is caused by supplying the gaseous processing fluid into the processing container 110, is suppressed.

According to an embodiment, in the pressure increasing operation ST2 and the distribution operation ST3, the processing fluid is supplied from the common fluid supplier 130 into the processing container 110. For this reason, the structure of the processor 2 is less complicated compared to the case where the processing fluid is supplied from different fluid suppliers to the processing container 110 in the pressure increasing operation ST2 and the distribution operation ST3.

### <First Direction Change Member>

A first direction change member 210 according to a first example will be described with reference to FIG. 4. The first direction change member 210 is applicable as the first direction change member 132 described above. FIG. 4 is a vertical cross-sectional view illustrating the first direction change member 210 according to the first example. FIG. 4 is a cross-sectional view taken along line A-A line as seen in the direction of arrow in FIG. 2. In FIG. 4, the illustration of the holder 120 is omitted.

The first direction change member 210 is provided in a supply space S2. The first direction change member 210 is a plate-shaped member having a flat plate shape extending along the X-axis direction and the Z-axis direction. The first direction change member 210 includes a plurality of holes 210h through which the processing fluid flows.

The plurality of holes 210h are provided along the X-axis direction. Each hole 210h may be arranged at a position in which each hole 210h is not aligned with each discharge port 131c in the X-axis direction. In this case, even when there are differences in a flow velocity distribution in the X-axis direction in the plurality of discharge ports 131c, the processing fluid may flow uniformly in the X-axis direction without being affected by such a flow velocity distribution. The plurality of holes 210h are provided along the Z-axis direction. The plurality of holes 210h are provided without including a height position of the substrate W held at the holding position. The plurality of holes 210h are provided, for example, above and below the height position of the substrate W held at the holding position.

According to the first direction change member 210, the plurality of holes 210h are provided without including the height position of the substrate W held at the holding position. In this case, as indicated by the arrows in FIG. 4, by the plurality of holes 210h, the flow of the processing fluid is changed to a flow in a direction that does not come in contact with the radial outer end of the substrate W. A difference between a height of the center of the hole 210h, among the plurality of holes 210h, which is provided at the height position closest to the height position of the substrate W held at the holding position, and a height of the center of the substrate W held at the holding position is, for example, 0.5 mm or more. Accordingly, there is no flow of the processing fluid from the plurality of discharge ports 131c directly toward the radial outer end of the substrate W. This suppresses evaporation of the liquid film on the radial outer end of the substrate W. As a result, the collapse of the pattern of the substrate W may be suppressed.

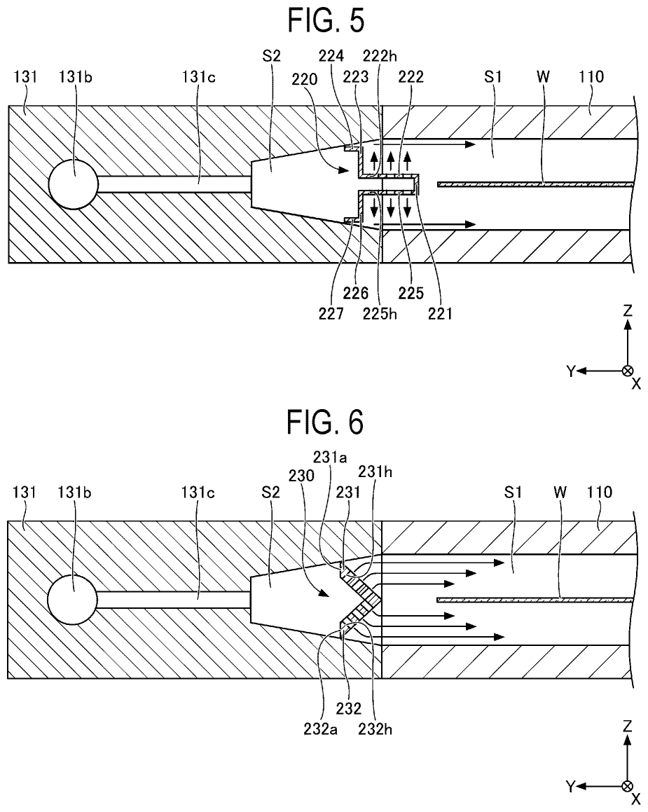

A first direction change member 220 according to a second example will be described with reference to FIG. 5. The first direction change member 220 is applicable as the first direction change member 132 described above. FIG. 5 is a vertical cross-sectional view illustrating the first direction change member 220 according to the second example. FIG. 5 is a cross-sectional view taken along line A-A line as seen in the direction of arrow in FIG. 2. In FIG. 5, the illustration of the holder 120 is omitted.

The first direction change member 220 is provided over the processing space S1 and the supply space S2. The first direction change member 220 extends along the X-axis direction.

The first direction change member 220 includes a central vertical portion 221, a first upper horizontal portion 222, an upper vertical portion 223, a second upper horizontal portion 224, a first lower horizontal portion 225, a lower vertical portion 226, and a second horizontal portion 227. The central vertical portion 221, the first upper horizontal portion 222, the upper vertical portion 223, the second upper horizontal portion 224, the first lower horizontal portion 225, the lower vertical portion 226, and the second horizontal portion 227 may be formed, for example, by a single seamless member. The central vertical portion 221, the first upper horizontal portion 222, the upper vertical portion 223, the second upper horizontal portion 224, the first lower horizontal portion 225, the lower vertical portion 226, and the second horizontal portion 227 may be formed by processing, for example, a plate-shaped member. The central vertical portion 221, the first upper horizontal portion 222, the upper vertical portion 223, the second upper horizontal portion 224, the first lower horizontal portion 225, the lower vertical portion 226, and the second horizontal portion 227 may be formed by bonding separate individual members to each other.

The central vertical portion 221 extends along the Z-axis direction, including the height position of the substrate W held at the holding position. The central vertical portion 221 extends from above an upper surface of the substrate W held at the holding position to below a lower surface of the substrate W held at the holding position. The central vertical portion 221 blocks the flow of the processing fluid.

The first upper horizontal portion 222 extends horizontally from the upper end of the central vertical section 221 in the positive Y-axis direction. The first upper horizontal portion 222 has a plurality of holes 222h through which the processing fluid can flow. The plurality of holes 222h are provided along the X-axis direction. Each hole 222h may be provided at a position at which each hole 222h is not aligned with each discharge port 131c in the X-axis direction. In this case, even when there are differences in a flow velocity distribution in the X-axis direction in the plurality of discharge ports 131c, the processing fluid may flow uniformly in the X-axis direction without being affected by such a flow velocity distribution. The plurality of holes 222h are provided along the Y-axis direction.

The upper vertical portion 223 extends vertically in the positive Z-axis direction from an end portion of the first upper horizontal portion 222 in the positive Y-axis direction.

The second upper horizontal section 224 extends horizontally from an upper end of the upper vertical section 223 in the positive Y-axis direction.

The first lower horizontal portion 225 extends horizontally from a lower end of the central vertical portion 221 in the positive Y-axis direction. The first lower horizontal portion 225 has a plurality of holes 225h through which the processing fluid flows. The plurality of holes 225h are provided along the X-axis direction. Each hole 225h may be provided at a position at which each hole 225h is not aligned with each discharge port 131c in the X-axis direction. In this case, even when there are differences in a flow velocity distribution in the X-axis direction in the plurality of discharge ports 131c, the processing fluid may flow uniformly in the X-axis direction without being affected by such a flow velocity distribution. The plurality of holes 225h are provided along the Y-axis direction.

The lower vertical portion 226 extends vertically in the negative Z-axis direction from an end portion of the first lower horizontal portion 225 in the positive Y-axis direction.

The second horizontal portion 227 extends horizontally from a lower end of the lower vertical portion 226 in the positive Y-axis direction.

According to the first direction change member 220, the central vertical portion 221 blocks the flow of the processing fluid directly toward the radial outer end of the substrate W. As indicated by the arrows in FIG. 5, by the plurality of holes 222h and 225h, the flow of the processing fluid is changed to be flows that are oriented upward and downward, respectively. Accordingly, there is no flow of the processing fluid from the plurality of discharge ports 131c directly toward the radial outer end of the substrate W. This suppresses evaporation of the liquid film on the radial outer end of the substrate W. As a result, the collapse of the pattern of the substrate W may be suppressed.

A first direction change member 230 according to a third example will be described with reference to FIG. 6. The first direction change member 230 is applicable as the first direction change member 132 described above. FIG. 6 is a vertical cross-sectional view illustrating the first direction change member 230 according to the third example. FIG. 6 is a cross-sectional view taken along line A-A line as seen in the direction of arrow in FIG. 2. In FIG. 6, the illustration of the holder 120 is omitted.

The first direction change member 230 is provided in the supply space S2. The first direction change member 230 extends along the X-axis direction. The first direction change member 230 is a plate-shaped member having a V shape tapering from the positive Y-axis direction to the negative Y-axis direction in a vertical cross-section orthogonal to the X-axis direction.

The first direction change member 230 includes an upper inclined portion 231 and a lower inclined portion 232. The upper inclined portion 231 and the lower inclined portion 232 are formed by, for example, a single seamless member. The upper inclined portion 231 and the lower inclined portion 232 are formed by processing, for example, a plate-shaped member. The upper inclined portion 231 and the lower inclined portion 232 may be formed by bonding separate individual members. A height position of a boundary between the upper inclined portion 231 and the lower inclined portion 232 is, for example, the same as the height position of the substrate W held at the holding position.

The upper inclined portion 231 is inclined upward from the negative Y-axis direction to the positive Y-axis direction. The upper inclined portion 231 has a plurality of holes 231h through which the processing fluid flows. The plurality of holes 231h are provided along the X-axis direction. Each hole 231h may be provided at a position at which each hole 231h is not aligned with each discharge port 131c in the X-axis direction. In this case, even when there are differences in flow a velocity distribution in the X-axis direction in the plurality of discharge ports 131c, the processing fluid may flow uniformly in the X-axis direction without being affected by such a flow velocity distribution. The plurality of holes 231h are provided along an inclined surface of the upper inclined portion 231. The plurality of holes 231h are not provided at the height position of the substrate W held at the holding position. Each hole 231h may be configured to discharge the processing fluid in a direction inclined with respect to the horizontal direction. For example, each hole 231h is formed along a thickness direction of the upper inclined portion 231 and configured to discharge the processing fluid in an oblique upward direction. In this case, compared to a case where holes are formed in a horizontal transverse direction, it is possible to more reliably eliminate the flow of the process fluid toward the radial outer end of the substrate W.

The lower inclined portion 232 is inclined downward from the negative Y-axis direction to the positive Y-axis direction. The lower inclined portion 232 has a plurality of holes 232h through which the processing fluid flows. The plurality of holes 232h are provided along the X-axis direction. Each hole 232h may be provided at a position at which each hole 232h is not aligned with each discharge port 131c in the X-axis direction. In this case, even when there are differences in a flow velocity distribution in the X-axis direction in the plurality of discharge ports 131c, the processing fluid may flow uniformly in the X-axis direction without being affected by such a flow velocity distribution. The plurality of holes 232h are provided along an inclined surface of the lower inclined portion 232. The plurality of holes 232h are not provided at the height position of the substrate W held at the holding position. Each hole 232h may be configured to discharge the processing fluid in a direction inclined with respect to the horizontal direction. For example, each hole 232h is formed along a thickness direction of the lower inclined portion 232 and configured to discharge the processing fluid in an oblique downward direction. In this case, compared to the case where the holes are formed in the horizontal transverse direction, it is possible to more reliably eliminate the flow of the process fluid toward the radial outer end of the substrate W.

The upper inclined portion 231 and the lower inclined portion 232 may have vertical surfaces 231a and 232a extending vertically at end portions (end portions distant from the substrate W) in the positive Y-axis direction, respectively. In this case, the processing fluid discharged from the discharge port 131c may collide with the vertical surfaces 231a and 232a to generate turbulence in the supply space S2, thereby making the flow of the processing fluid from the plurality of holes 231h and 232h uniform.

According to the first direction change member 230, the upper inclined portion 231 and the lower inclined portion 232 block the flow of the processing fluid directly toward the radial outer end of the substrate W. As indicated by the arrows in FIG. 6, by the plurality of holes 231h and 232h, the flow of the processing fluid is changed to be flows that are oriented upward and downward, respectively. Accordingly, there is no flow of the processing fluid from the plurality of discharge ports 131c directly toward the radial outer end of the substrate W. This suppresses evaporation of the liquid film on the radial outer end of the substrate W. As a result, the collapse of the pattern of the substrate W may be suppressed.

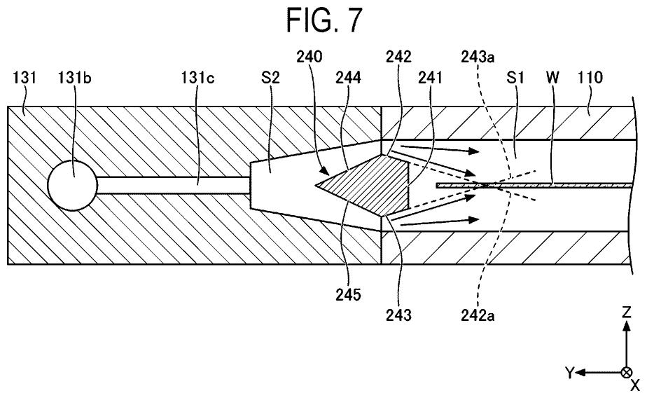

A first direction change member 240 according to a fourth example will be described with reference to FIG. 7. The first direction change member 240 is applicable as the first direction change member 132 described above. FIG. 7 is a vertical cross-sectional view illustrating the first direction change member 240 according to the fourth example. FIG. 7 is a cross-sectional view taken along line A-A line as seen in the direction of arrow in FIG. 2. In FIG. 7, the illustration of the holder 120 is omitted.

The first direction change member 240 is provided over the processing space S1 and the supply space S2. The first direction change member 240 extends along the X-axis direction. The first direction change member 240 has a pentagonal shape in a vertical cross-section orthogonal to the X-axis direction. The first direction change member 240 includes a vertical surface 241, a first upper inclined surface 242, a first lower inclined surface 243, a second upper inclined surface 244, and a second lower inclined surface 245.

The vertical surface 241 extends along the Z-axis direction, including the height position of the substrate W held at the holding position. The vertical surface 241 extends from above the upper surface of the substrate W held at the holding position to below the lower surface of the substrate W held at the holding position.

The first upper inclined surface 242 extends upward from an upper end of the vertical surface 241 in the positive Y-axis direction. A first virtual surface 242a, which is obtained by extending the first upper inclined surface 242 in the negative Y-axis direction, intersects the substrate W on the side in the negative Y-axis direction rather than the radial outer end of the substrate W in the positive Y-axis direction. In this case, as indicated by the arrows in FIG. 7, the flow of the processing fluid discharged from the plurality of discharge ports 131c is changed to a flow directed further inward from the radial outer end of the substrate W held at the holding position.

The first lower inclined surface 243 extends downward from a lower end of the vertical surface 241 in the positive Y-axis direction. A second virtual surface 243a, which is obtained by extending the first lower inclined surface 243 in the negative Y-axis direction, intersects the substrate W at the side of the negative Y-axis direction rather than the radial outer end of the substrate W in the positive Y-axis direction. In this case, as indicated by the arrows in FIG. 7, the flow of the processing fluid discharged from the plurality of discharge ports 131c is changed to a flow directed further inward than the radial outer end of the substrate W held at the holding position.

The second upper inclined surface 244 extends downward in the positive Y-axis direction from an end portion of the first upper inclined surface 242 in the positive Y-axis direction.

The second lower inclined surface 245 extends upward in the positive Y-axis direction from an end portion of the first lower inclined surface 243 in the positive Y-axis direction. The end portion of the second lower inclined surface 245 in the positive Y-axis direction is connected to the end portion of the second upper inclined surface 244 in the positive Y-axis direction. A height position of a boundary between the second upper inclined surface 244 and the second lower inclined surface 245 is, for example, the same as the height position of the substrate W held at the holding position. In this case, the processing fluid is evenly distributed in the vertical direction.

According to the first direction change member 240, the first upper inclined surface 242 and the first lower inclined surface 243 change the flow of the processing fluid to flows directed further inward from the radial outer end of the substrate W held at the holding position. Accordingly, there is no flow of the processing fluid from the plurality of discharge ports 131c directly toward the radial outer end of the substrate W. This suppresses evaporation of the liquid film on the radial outer end of the substrate W. As a result, the collapse of the pattern of the substrate W may be suppressed.

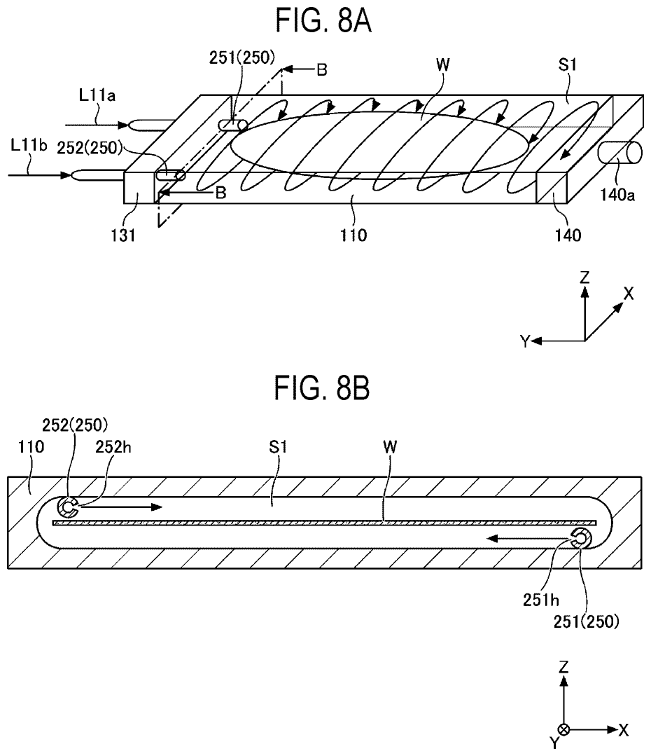

A first direction change member 250 according to a fifth example will be described with reference to FIGS. 8A and 8B. The first direction change member 250 is applicable as the first direction change member 132 described above. FIGS. 8A and 8B illustrate the first direction change member 250 according to the fifth example. FIG. 8A is a perspective view illustrating the first directional change member 250. FIG. 8B is a cross-sectional view taken along line B-B line as seen in the direction of arrow in FIG. 8A. In FIGS. 8A and 8B, the illustration of the holder 120 is omitted.

The first direction change member 250 includes a first nozzle 251 and a second nozzle 252. The first nozzle 251 and the second nozzle 252 are provided to be spaced apart from each other in the X-axis direction.

The first nozzle 251 is provided at an end portion of the first direction change member 250 in the positive X-axis direction. The first nozzle 251 is positioned below the lower surface of the substrate W held at the holding position. The first nozzle 251 extends in the Y-axis direction. An end portion of the first nozzle 251 in the positive Y-axis direction is connected to the first branch channel L11a. The first nozzle 251 is supplied with the processing fluid F from the first branch channel L11a. An end portion of the first nozzle 251 in the negative Y-axis direction is closed. The first nozzle 251 has a hole 251h through which the processing fluid flows. For example, the hole 251h is provided in the processing space S1. The hole 251h may also be provided in the supply space S2. The hole 251h is provided toward the second nozzle 252. The first nozzle 251 discharges the processing fluid horizontally from the hole 251h in the negative X-axis direction.

The second nozzle 252 is provided at an end portion of the first direction change member 250 in the negative X-axis direction. The second nozzle 252 is provided above the upper surface of the substrate W held at the holding position. The second nozzle 252 extends in the Y-axis direction. An end portion of the second nozzle 252 in the positive Y-axis direction is connected to the second branch channel Li ib. The second nozzle 252 is supplied with the processing fluid F from the second branch channel Li ib. An end portion of the second nozzle 252 in the negative Y-axis direction is closed. The second nozzle 252 has a hole 252h through which the processing fluid flows. For example, the hole 252h is provided in the processing space S1. The hole 252h may also be provided in the supply space S2. The hole 252h is provided toward the first nozzle 251. The second nozzle 252 discharges the processing fluid horizontally from the hole 252h in the positive X-axis direction.

According to the first direction change member 250, the processing fluid discharged from the hole 251h and the processing fluid discharged from the hole 252h form a spiral flow that rotates around the Y-axis. That is, according to the first direction change member 250, by the hole 251h and the hole 252h, the flow of the processing fluid supplied to the first nozzle 251 and the second nozzle 252 is changed into the spiral flow that rotates around the Y-axis. Accordingly, there is no flow of the processing fluid from the first nozzle 251 and the second nozzle 252 directly toward the radial outer end of the substrate W. This suppresses evaporation of the liquid film on the radial outer end of the substrate W. As a result, the collapse of the pattern of the substrate W may be suppressed.

In the example illustrated in FIGS. 8A and 8B, the discharge port 140a is provided on the side of the negative Y-axis direction, but as in the example of FIG. 2, the discharge port 140a may be provided on the side of the negative Z-axis direction between the cover 140 and the processing container 110.

### <Second Direction Change Member>

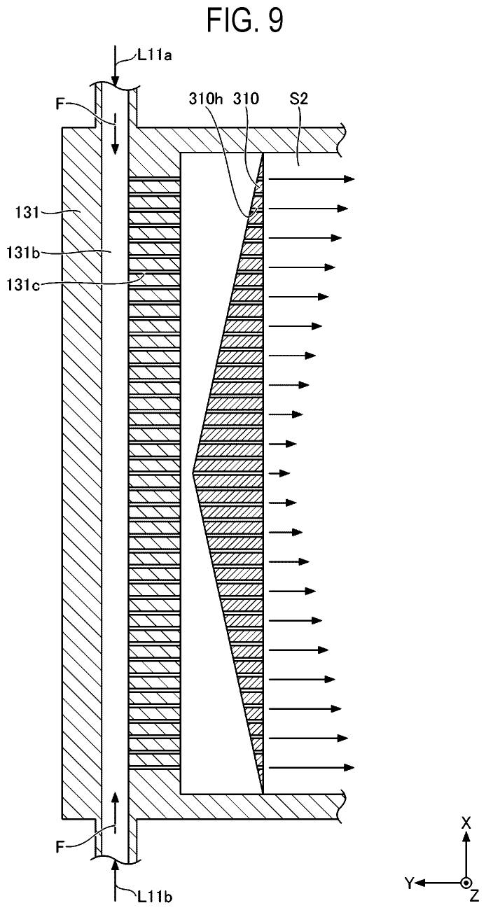

A second direction change member 310 according to a first example will be described with reference to FIG. 9. The second direction change member 310 is applicable as the second direction change member 133 described above. FIG. 9 is a horizontal cross-sectional view illustrating the second direction change member 310 according to the first example.

The second direction change member 310 is provided in the supply space S2. The second direction change member 310 extends along the X-axis direction and the Z-axis direction. In a length of the second direction change member 310 in the Y-axis direction, the central portion in the X-axis direction is longer than both end portions in the X-axis direction. The second direction change member 310 has a plurality of holes 310h through which the processing fluid flows.

The plurality of holes 310h are provided along the X-axis direction. The plurality of holes 310h are provided along the Z-axis direction. Each hole 310h is formed to pass through the second direction change member 310 in the positive and negative Y-axis directions. The length of the holes 310h in the Y-axis direction increases from both end portions in the X-axis direction toward the central portion. For example, inner diameters of the holes 310h are equal to each other. As a result, the central portion in the X-axis direction includes a path formed to have conductance lower than those of both end portions.

According to the second direction change member 310, by the plurality of holes 310h, the path is formed to have a relatively low conductance at the central portion rather than at both end portions in the X-axis direction. As a result, the flow velocity of the processing fluid at the central portion in the X-axis direction becomes lower than the flow velocity of the processing fluid at both end portions in the X-axis direction. This makes it possible to suppress the collapse of the pattern of the substrate W.

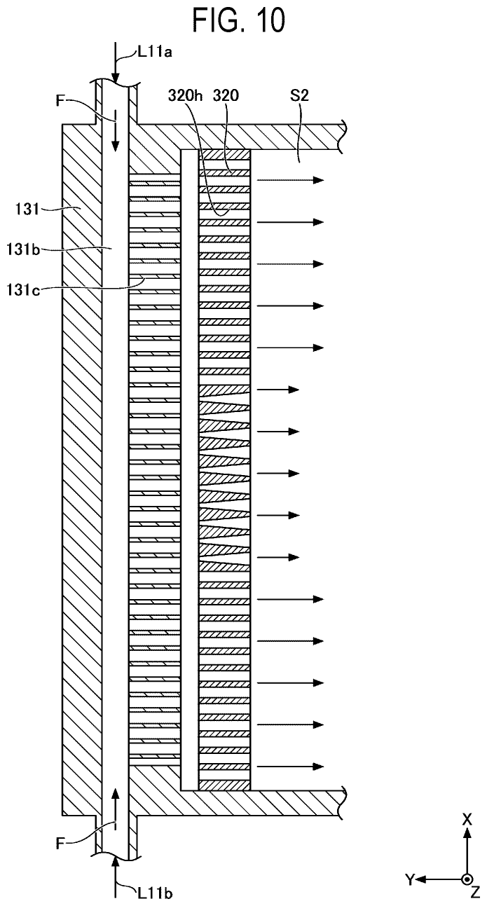

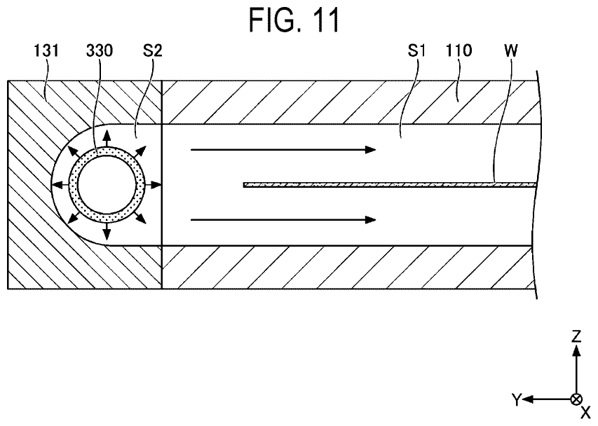

A second direction change member 320 according to a second example will be described with reference to FIG. 10. The second direction change member 320 is applicable as the second direction change member 133 described above. FIG. 10 is a horizontal cross-sectional view illustrating the second direction change member 320 according to the second example.

The second direction change member 320 is provided in the supply space S2. The second direction change member 320 has a flat plate shape extending along the X-axis direction and the Z-axis direction. The second direction change member 320 has a plurality of holes 320h through which the processing fluid flows.

The plurality of holes 320h are provided along the X-axis direction. The plurality of holes 320h are provided along the Z-axis direction. Each hole 320h is formed to pass through the second direction change member 320 in the positive and negative Y-axis directions. An opening of each hole 320h positioned at the central portion in the X-axis direction is larger in inner diameter in the positive Y-axis direction than an opening of each hole 320h positioned at both end portions in the X-axis direction. Thus, paths are formed to have a relatively low conductance at the central portion rather than at both end portions in the X-axis direction. The inner diameter of each hole 320h positioned at the central portion in the X-axis direction may be increased from the positive Y-axis direction to the negative Y-axis direction.

According to the second direction change member 320, by the plurality of holes 320h, the paths are formed to have a relatively low conductance at the central portion rather than at both end portions in the X-axis direction. As a result, the flow velocity of the processing fluid in the central portion in the X-axis direction becomes lower than the flow velocity of the processing fluid at both end portions in the X-axis direction. This makes it possible to suppress the collapse of the pattern of the substrate W.

A second direction change member 330 according to a third example will be described with reference to FIG. 11. The second direction change member 330 is applicable as the second direction change member 133 described above. FIG. 11 is a vertical cross-sectional view illustrating the second direction change member 330 according to the third example. FIG. 11 is a cross-sectional view taken along line A-A as seen in the direction of arrow in FIG. 2. In FIG. 11, the illustration of the holder 120 is omitted.

The second direction change member 330 is provided in the supply space S2. The second direction change member 330 has a cylindrical shape extending along the X-axis direction. The processing fluid is introduced from the first branch channel L11a and the second branch channel L11b into the second direction change member 330. The second direction change member 330 is formed with a mesh member. In this case, the processing fluid introduced into the second direction change member 330 is diffused in all directions. Thus, the overall flow velocity of the processing fluid, including the flow toward the radial outer end of the substrate W, is reduced. This makes it possible to suppress the collapse of the pattern of the substrate W.

### <Modification of Fluid Supplier>

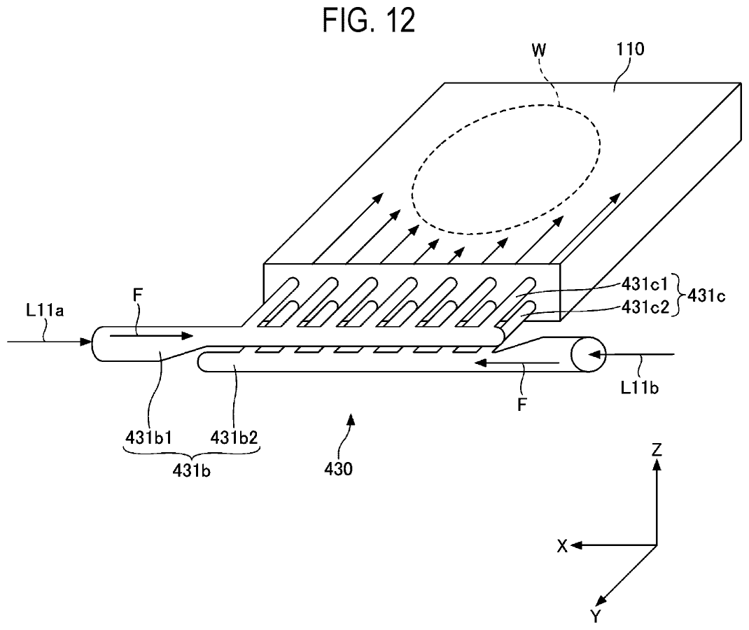

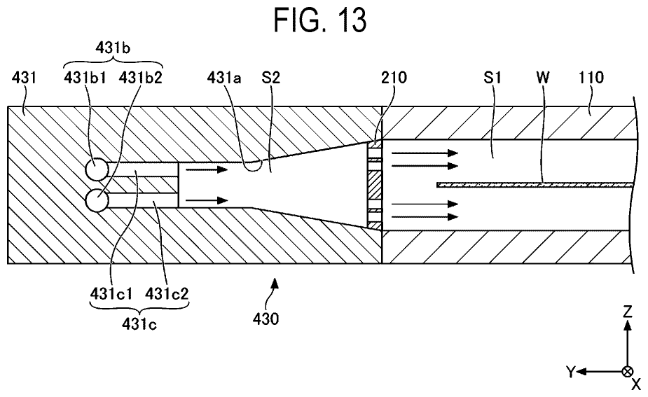

A fluid supplier 430 according to a modification will be described with reference to FIGS. 12 and 13. FIG. 12 is a schematic perspective view illustrating the fluid supplier 430 according to the modification. FIG. 13 is a vertical cross-sectional view illustrating the fluid supplier 430 according to the modification.

The fluid supplier 430 according to the modification differs from the fluid supplier 130 in that the fluid supplier 430 includes a supply body 431 instead of the supply body 131. Other configurations of the fluid supplier 430 may be identical to those of the fluid supplier 130. Hereinafter, configurations of the fluid supplier 430, which are different from those of the fluid supplier 130, will be mainly described.

The fluid supplier 430 includes the supply body 431 and the first direction change member 210. The supply body 431 is an example of a flow velocity distribution changer. The fluid supplier 430 may include the above-described first direction change member 220, 230, or 240 instead of the first direction change member 210. The fluid supplier 430 may further include the second direction change member 133.

The supply body 431 covers the opening of the processing space S1 in the positive Y-axis direction. A sealing member (not illustrated) is provided between the supply body 431 and the processing container 110. The sealing member ensures air tightness of the processing space S1 between the fluid supplier 430 and the processing container 110. The supply body 431 includes a concave portion 431a, an inner channel 431b, and discharge ports 431c.

The concave portion 431a is provided at a side of the processing space S1 of the supply body 431. The concave portion 431a forms the supply space S2 communicating with the processing space S1.

The inner channel 431b is provided in the supply body 431. The inner channel 431b is positioned at an upstream side of the flow of the process fluid F rather than the first direction change member 210. The inner channel 431b includes a first fluid channel 431b1 and a second fluid channel 431b2.

The first fluid channel 431b1 extends along the X-axis direction. The first fluid channel 431b1 is open in the positive X-axis direction and closed in the negative X-axis direction. The first branch channel L11a branched at the supply channel L11 is connected to the opening of the first fluid channel 431b1 in the positive X-axis direction. The first fluid channel 431b1 is supplied with the processing fluid F from the first branch channel L11a. Thus, in the first fluid channel 431b1, the processing fluid F flows from the positive X-axis direction to the negative X-axis direction. The first fluid channel 431b1 is configured such that a portion positioned in the positive X-axis direction from a portion, in which a plurality of first discharge ports 431c1 (to be described later) is provided, has a relatively larger channel cross-sectional area than the portion in which the plurality of first discharge ports 431c1 is provided. However, the first fluid channel 431b1 may have a constant cross-sectional area from the negative X-axis direction to the positive the X-axis direction.

The second fluid channel 431b2 extends along the X-axis direction. The second fluid channel 431b2 is provided parallel to the first fluid channel 431b1. For example, the second fluid channel 431b2 is provided on the side in the negative Z-axis direction from the first fluid channel 431b1. The second fluid channel 431b2 may be provided on the side in the positive Z-axis direction from the first fluid channel 431b1. For example, in the Y-axis direction, a position of the second fluid channel 431b2 is the same as that of the first fluid channel 431b1. The second fluid channel 431b2 may be provided on the side in the positive Y-axis direction from the first fluid channel 431b1, or on the side in the negative Y-axis direction from the first fluid channel 431b1. For example, in the X-axis direction, a length of the second fluid channel 431b2 is the same as that of the first fluid channel 431b1. The second fluid channel 431b2 is provided so as not to communicate with the first fluid channel 431b1.

The second fluid channel 431b2 is open in the negative X-axis direction and closed in the positive X-axis direction. The second branch channel L11b branched at the supply channel L11 is connected to the opening of the second fluid channel 431b2 in the negative X-axis direction. The second fluid channel 431b2 is supplied with the processing fluid F from the second branch channel L11b. Thus, in the second fluid channel 431b2, the processing fluid F flows from the negative X-axis direction to the positive X-axis direction. That is, the first fluid channel 431b1 and the second fluid channel 431b2 cause the processing fluid F to flow in different directions in the X-axis direction. The second fluid channel 431b2 is configured such that a portion positioned in the negative X-axis direction from a portion, in which a plurality of first discharge ports 431c2 (to be described later) is provided, has a relatively larger channel cross-sectional area than the portion in which the plurality of first discharge ports 431c2 is provided. However, the second fluid channel 431b2 may have a constant cross-sectional area from the negative X-axis direction to the positive the X-axis direction.

Each discharge port 431c includes a first discharge port 431c1 and a second discharge port 431c2.

A plurality of first discharge ports 431c1 is provided to be spaced apart from each other along the extension direction (the X-axis direction) of the first fluid channel 431b1. Each of the first discharge ports 431c1 extends along the Y-axis direction. Through each of the first discharge ports 431c1, the first fluid channel 431b1 is in communication with the supply space S2. Each of the first discharge ports 431c1 discharges the processing fluid F toward the supply space S2. Opening diameters of the plurality of first discharge ports 431c1 are equal to each other, for example. Among the plurality of first discharge ports 431c1, the opening diameter of the first discharge port 431c1 provided at the central portion in the X-axis direction may be larger than the opening diameters of the first discharge ports 431c1 provided at both end portions in the X-axis direction. In this case, a flow velocity of the processing fluid F discharged from the first discharge port 431c1 provided at the central portion in the X-axis direction becomes lower than that of the processing fluid F discharged from the first discharge ports 431c1 at both end portions in the X-axis direction.

A plurality of second discharge ports 431c2 is provided to be spaced apart from each other along the extension direction (X-axis direction) of the second fluid channel 431b2. Each of the second discharge ports 431c2 extends along the Y-axis direction. Through each of the second discharge ports 431c2, the second fluid channel 431b2 is in communication with the supply space S2. Each of the second discharge ports 431c2 discharges the processing fluid F toward the supply space S2. Opening diameters of the plurality of second discharge ports 431c2 are equal to each other, for example. Among the plurality of second discharge ports 431c2, the opening diameter of the second discharge port 431c2 provided at the central portion in the X-axis direction may be larger than those of the second discharge ports 431c2 provided at both end portions in the X-axis direction. In this case, a flow velocity of the processing fluid F discharged from the second discharge port 431c2 provided at the central portion in the X-axis direction becomes lower than that of the processing fluid F discharged from the second discharge ports 431c2 provided at both end portions in the X-axis direction.

In the fluid supplier 430, it is considered that the processing fluid F is supplied from the first branch channel L11a to the first fluid channel 431b1 and from the second branch channel L11b to the second fluid channel 431b2. In this case, the processing fluid F flows through the first fluid channel 431b1 from the positive X-axis direction to the negative X-axis direction. Thus, a static pressure at the central portion of the first fluid channel 431b1 in the X-axis direction is lower than that on the side in the negative X-axis direction. Therefore, the flow velocity of the processing fluid F discharged from the first discharge port 431c1 provided at the central portion of the first fluid channel 431b1 in the X-axis direction is lower than that of the processing fluid F discharged from the first discharge port 431c1 provided on the side in the negative X-axis direction. In the second fluid channel 431b2, the processing fluid F flows from the negative X-axis direction to the positive X-axis direction. Thus, a static pressure at the central portion of the second fluid channel 431b2 in the X-axis direction is lower than that on the side in the positive X-axis direction. Therefore, the flow velocity of the processing fluid F discharged from the second discharge port 431c2 provided at the central portion of the second fluid channel 431b2 in the X-axis direction is lower than that of the processing fluid F discharged from the second discharge ports 431c2 provided on the side in the positive X-axis direction. As a result, the flow velocity of the processing fluid F at the central portion in the X-axis direction is lower than that of the processing fluid F at both end portions in the X-axis direction.

The fluid supplier 430 may further include a merging member (not illustrated) that merges the processing fluid F from each of the first discharge ports 431c1 and the processing fluid F from each of the second discharge ports 431c2. For example, the merging member is detachably attached to the supply space S2. The merging member merges the processing fluid F from each of the first discharge ports 431c1 and the processing fluid F from each of the second discharge ports 431c2 before they are discharged into the supply space S2, and then discharges the merged processing fluid F into the supply space S2. In this case, it is easy to suppress the flow of the processing fluid F on the substrate W from being deviated.

According to the present disclosure, it is possible to suppress collapse of a pattern of a substrate.

The embodiments disclosed herein should be considered as illustrative and not restrictive in all respects. The above-described embodiments may be omitted, substituted, or modified in various forms without departing from the scope and sprit of the appended claims.

In the above-described embodiment, the case where the second direction change member 133 and the first direction change member 132 are provided in this order from the discharge ports 131c toward the substrate W held at the holding position has been described, but the present disclosure is not limited thereto. For example, the first direction change member 132 and the second direction change member 133 may be provided in this order from the discharge ports 131c toward the substrate W held at the holding position. For example, the second direction change member 133 may not be provided. For example, the second direction change member 133 may be provided in multiple stages between the discharge ports 131c and the first direction change member 132.

What is claimed is:

1. A substrate processing apparatus, comprising:
a processing container in which the substrate is accommodated;
a holder configured to hold the substrate in a horizontal posture at a holding position inside the processing container; and
a fluid supplier configured to supply, into the processing container, a supercritical processing fluid for drying the substrate to which a liquid adheres,
wherein the fluid supplier includes a first direction change member configured to change a flow of the supercritical processing fluid which is supplied radially outward from the substrate held by the holder, in a direction that does not come in contact with a radial outer end of the substrate.

2. The substrate processing apparatus of claim 1, further comprising a controller,
wherein the controller is configured to execute an operation of discharging the supercritical processing fluid from the fluid supplier into the processing container when increasing a pressure in an interior of the processing container.

3. The substrate processing apparatus of claim 2, wherein the controller is configured to execute the operation of discharging the supercritical processing fluid from the fluid supplier toward the interior of the processing container when simultaneously performing supplying the supercritical processing fluid into the processing container and discharging the supercritical processing fluid from the interior of the processing container.

4. The substrate processing apparatus of claim 1, wherein the first direction change member is a plate-shaped member having a plurality of holes through which the supercritical processing fluid flows.

5. The substrate processing apparatus of claim 4, wherein the plate-shaped member has a flat plate shape extending along a vertical direction, and
wherein the plurality of holes are provided above and below a height position at which the substrate is provided.

6. The substrate processing apparatus of claim 4, wherein the plate-shaped member includes:
a vertical portion extending along a vertical direction, including a height position at which the substrate is provided;
an upper horizontal portion extending in a direction away from the substrate from an upper end of the vertical portion in a horizontal direction; and
a lower horizontal portion extending in the direction away from the substrate from a lower end of the vertical portion in the horizontal direction,
wherein the plurality of holes are provided in the upper horizontal portion and the lower horizontal portion.

7. The substrate processing apparatus of claim 4, wherein the plate-shaped member has a V shape tapering toward the substrate in a vertical cross-section, and
wherein the plurality of holes are provided at a height above and below a height position at which the substrate is provided.

8. The substrate processing apparatus of claim 7, wherein the supercritical processing fluid is discharged via each of the plurality of holes in a direction inclined with respect to the horizontal direction.

9. The substrate processing apparatus of claim 7, wherein the plate-shaped member has a vertical surface extending vertically at an end portion distant from the substrate.

10. The substrate processing apparatus of claim 1, wherein the first direction change member includes:
a vertical surface extending along a vertical direction, including a height position at which the substrate is provided; and
an upper inclined surface extending upward from an upper end of the vertical surface in a direction away from the substrate; and
a lower inclined surface extending downward from a lower end of the vertical surface in the direction away from the substrate.

11. The substrate processing apparatus of claim 1, wherein the first direction change member is configured to change the flow of the supercritical processing fluid into a spiral flow.

12. The substrate processing apparatus of claim 1, wherein the fluid supplier includes a second direction change member configured to change a horizontal flow of the supercritical processing fluid supplied radially outward from the substrate held by the holder.

13. The substrate processing apparatus of claim 12, wherein the second direction change member has a path in which a central portion of the path in a horizontal direction is smaller in conductance than both end portions of the path.

14. The substrate processing apparatus of claim 12, wherein the second direction change member is configured to diffuse the supercritical processing fluid in all directions.

15. The substrate processing apparatus of claim 1, wherein the fluid supplier includes a flow velocity distribution changer configured to make a flow velocity of a central portion in a horizontal direction in the flow of the supercritical processing fluid, which is supplied radially outward from the substrate held by the holder, smaller than flow velocities of both end portions in the horizontal direction in the flow.

16. The substrate processing apparatus of claim 15, wherein the flow velocity distribution changer has a fluid channel provided at an upstream side of the flow of the supercritical processing fluid than the first direction change member

17. The substrate processing apparatus of claim 15, wherein the flow velocity distribution changer includes:
a fluid channel extending along the horizontal direction; and
a plurality of discharge ports spaced apart from each other along an extension direction of the fluid channel to be in communication with the fluid channel,
wherein, among the plurality of discharge ports, the discharge port provided at the central portion in the horizontal direction is larger in diameter than the discharge ports provided at both end portions in the horizontal direction.

18. The substrate processing apparatus of claim 15, wherein the flow velocity distribution changer includes a first fluid channel and a second fluid channel through which the supercritical processing fluid flows in different directions in the horizontal direction, and
wherein the first fluid channel and the second fluid channel are arranged so as not to communicate with each other.

19. A substrate processing method used in a substrate processing apparatus,
wherein the substrate processing apparatus includes:
a processing container in which a substrate is accommodated;
a holder configured to hold the substrate in a horizontal posture at a holding position inside the processing container; and
a fluid supplier configured to supply, into the processing container, a supercritical processing fluid for drying the substrate to which a liquid adheres, and including a first direction change member configured to change a flow of the supercritical processing fluid, supplied radially outward from the substrate held by the holder, in a direction that does not come in contact with a radial outer end of the substrate,
the substrate processing method comprises:
discharging the supercritical processing fluid from the fluid supplier into the processing container when increasing a pressure in an interior of the processing container.

20. The substrate processing method of claim 19, further comprising: discharging the supercritical processing fluid from the fluid supplier toward the interior of the processing container when simultaneously performing supplying the supercritical processing fluid into the processing container and discharging the supercritical processing fluid from the interior of the processing container.
